(19) United States
(12) Patent Application Publication
(10) Pub. No.: US 2013/0049009 A1
(43) Pub. Date: Feb. 28, 2013

(54) Substrate For Vertical Light-Emitting Diode

(71) Applicants: KyoungJun Kim, ChungCheongNam-Do (KR); JongSe Park, ChungCheongNam-Do (KR); Donghyun Kim, ChungCheongNam-Do (KR); Bohyun Lee, ChungCheongNam-Do (KR); MinJu Kim, ChungCheongNam-Do (KR); BongHee Jang, ChungCheongNam-Do (KR)

(72) Inventors: KyoungJun Kim, ChungCheongNam-Do (KR); JongSe Park, ChungCheongNam-Do (KR); Donghyun Kim, ChungCheongNam-Do (KR); Bohyun Lee, ChungCheongNam-Do (KR); MinJu Kim, ChungCheongNam-Do (KR); BongHee Jang, ChungCheongNam-Do (KR)

(73) Assignee: SAMSUNG CORNING PRECISION MATERIALS CO., LTD., Gyeongsangbuk-do (KR)

(21) Appl. No.: 13/596,372

(22) Filed: Aug. 28, 2012

(30) Foreign Application Priority Data
Aug. 31, 2011 (KR) 10-2011-0087954

(51) Int. Cl. H01L 33/32; H01L 33/60

(52) U.S. Cl. 257/76; 438/29; 257/E33.025; 257/E33.072

(57) ABSTRACT

A multi-layer substrate for a vertical light-emitting diode (LED) includes a conductive and reflective base substrate and an n-type gallium nitride (GaN) layer formed on the base substrate.

### CROSS REFERENCE TO RELATED APPLICATION

The present application claims priority from Korean Patent Application Number 10-2011-0087954 filed on Aug. 31, 2011, the entire contents of which application are incorporated herein for all purposes by this reference.

### BACKGROUND OF THE INVENTION

1. Field of the Invention

The present invention relates to a substrate for a light-emitting diode (LED), and more particularly, to a substrate for a vertical LED.

2. Description of Related Art

In general, nitrides of group III elements, such as gallium nitride (GaN) and aluminum nitride (AlN), have high thermal stability and a direct transition type energy band structure. Owing to these properties, nitrides of group III elements are recently gaining attention as materials for light-emitting diodes (LEDs) in blue and ultraviolet (UV) ranges. In particular, blue and green LEDs using GaN are used in a variety of applications such as large-scale full-color flat displays, traffic lights, indoor lighting, high-density light sources, high-resolution output systems, optical communication, and the like.

LEDs using such chemical semiconductors developed from a traditional epi-up structure to a flip-chip structure, and are changing into a vertical structure for the purpose of high efficiency and high luminance.

Such vertical LEDs have a high yield since a greater number of LEDs are produced from the same wafer than are horizontal LEDs. The flow of current is efficient and mesa etching is not required. Therefore, processing is simple and a light-emitting structure can be prevented from being damaged.

FIG. 1 and FIG. 2 are cross-sectional views depicting a vertical LED of the related art.

Describing a process of fabricating a vertical GaN LED of the related art with reference to FIG. 1 and FIG. 2, an n-type GaN layer 20, an active layer 30, and a p-type GaN layer 40 are crystallized and grown sequentially on a sapphire substrate 10, a p-type electrode or a structure including the p-type electrode and a reflective layer 50 is formed on the p-type GaN layer 40, and then a bonding layer 60 is provided.

Afterwards, the bonding layer 60 is subjected to a predetermined temperature and pressure. A silicon (Si) substrate 70 is then bonded onto the bonding layer 60, thereby producing an LED structure.

After that, as shown in FIG. 2, the sapphire substrate 10 is removed via laser lift-off (LLO) or chemical lift-off (CLO). In sequence, an n-type electrode 80 is formed on the n-type GaN layer 20, followed by a device isolation process via laser scribing, wet etching or dry etching. Alternatively, the n-type electrode 80 is formed after the device isolation process.

The LED fabrication process including the LLO or CLO as described above solved some problems of the related art. Specifically, the traditional epi-up structure required to expose the n-type GaN layer by etching from the p-type GaN layer to the n-type GaN layer and to form the n-type electrode on the exposed n-type GaN layer, since the sapphire substrate is nonconductive. This fabrication process also increased the efficiency and power of LEDs.

However, this fabrication process has problems in that additional processes, such as bonding onto a silicon (Si) substrate, LLO or CLO, are required after the epitaxial process and that the use of the Si substrate must be added.

The information disclosed in this Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a substrate for a vertical light-emitting (LED) with which the vertical LED can be fabricated by a more simplified process.

In an aspect of the present invention, provided is a multi-layer substrate for a vertical light-emitting diode. The multi-layer substrate includes a conductive and reflective base substrate; and an n-type gallium nitride (GaN) layer formed on the base substrate.

In an exemplary embodiment, the base substrate may be a single layer.

In an exemplary embodiment, the base substrate may include a conductive layer and a reflective layer formed on the conductive layer, and the n-type GaN layer may be formed on the reflective layer.

In an exemplary embodiment, the multi-layer substrate may further include a bonding layer interposed between the conductive layer and the reflective layer and an anti-diffusion layer interposed between the bonding layer and the reflective layer.

In addition, the conductive layer may contain one selected from the group consisting of Si, GaAs, GaP, AlGaINP, Ge, SiSe, GaN, AlInGaN and InGaN.

Alternatively, the conductive layer may contain one selected from the group consisting of Al, Zn, Ag, W, Ti, Ni, Au, Mo, Pt, Pd, Cu, Cr, Fe and alloys thereof.

In addition, the reflective layer may contain one selected from the group consisting of Ag, Al, Zn, Au, Pt, Ti, Ge, Cu and Ni.

In an exemplary embodiment, the reflectance of the base substrate may be 50% or greater with respect to light that has a wavelength of 300 nm or greater.

In an exemplary embodiment, the coefficient of thermal expansion of the base substrate may range from 2.5 to 7.5.

It is preferred that the coefficient of thermal expansion of the base substrate may range from 4.1 to 6.9.

In an exemplary embodiment, the thickness of the base substrate may be 700 μm or greater.

It is preferred that the thickness of the base substrate may be 1000 μm or greater.

According to embodiments of the invention, since a vertical LED can be fabricated without an additional process such as bonding or LLO, the process of fabricating the vertical LED is simplified and its yield is improved.

In addition, fabrication cost can be reduced since the bonding process does not necessarily require the use of an additional substrate such as a silicon (Si) substrate.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 and FIG. 2 are cross-sectional views depicting a vertical LED of the related art;

FIG. 3 is a schematic cross-sectional view depicting a substrate for a vertical LED according to an exemplary embodiment of the invention in which a conductive and reflective base substrate is embodied as a single layer; and

FIG. 4 is a schematic-cross-sectional view depicting a substrate for a vertical LED according to another exemplary embodiment of the invention in which a conductive and reflective base substrate is embodied as a multilayer structure.

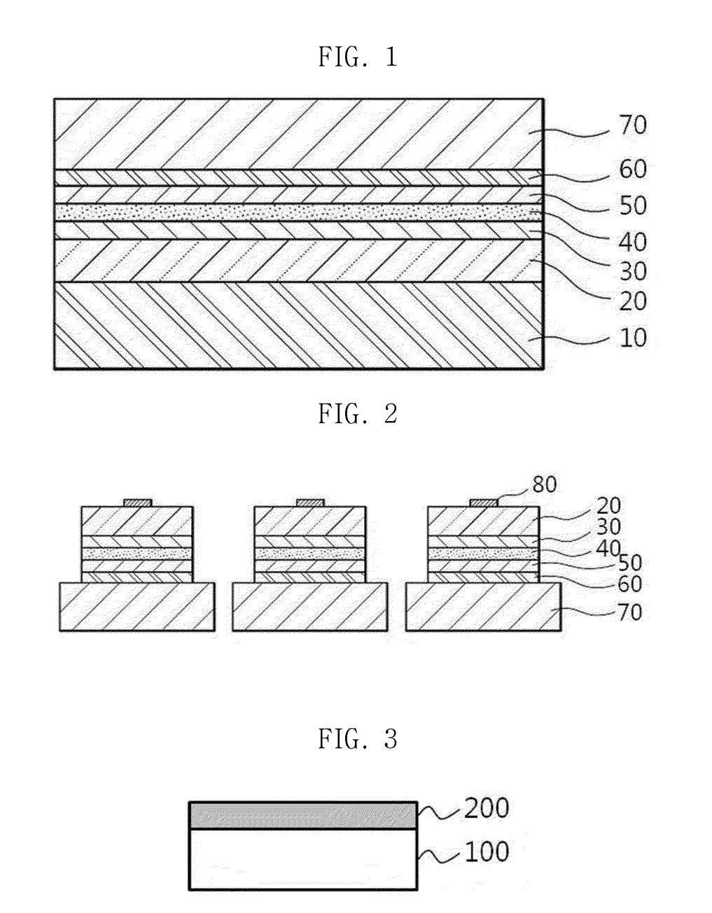

### DETAILED DESCRIPTION OF THE INVENTION

Reference will now be made in detail to a vertical LED of the present invention, embodiments of which are illustrated in the accompanying drawings and described below, so that a person having ordinary skill in the art to which the present invention relates can easily put the present invention into practice.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

FIG. 3 is a schematic cross-sectional view depicting a substrate for a vertical LED according to an exemplary embodiment of the invention which includes a single layer formed of a conductive and reflective base substrate.

The use of a substrate for a vertical LED requires that the substrate be conductive, that the epitaxial process face be not subjected to luminance degradation attributable to light absorption, and that the substrate have a surface on which n-type GaN can be grown.

Accordingly, the substrate for a vertical LED of the invention can include a base substrate and an n-type GaN layer.

The base substrate 100 acts as both a backing layer of the substrate for a vertical LED and an electrode in a final LED device, and is conductive and reflective.

It is preferred that the reflectance of the base substrate 100 be 50% (preferably 60%, more preferably 80%) or greater with respect to light that has a wavelength of 300 nm or greater (in particular, a wavelength of 300-1000 nm).

The coefficient of thermal expansion (CTE) of the base substrate 100 is required to show a good match with that of GaN. This property prevents malfunctions and optical efficiency reduction by decreasing strain and improving crystallinity when an active layer and a p-type GaN layer is deposited in the process of fabricating an LED using the substrate for an LED according to an embodiment the invention. Therefore, the CTE of the base substrate may range from 2.5 to 7.5, preferably from 4.0 to 7.0, and more preferably, from 4.1 to 6.9.

In addition, the thickness of the base substrate 100 may be 700 μm or more, and more preferably 1000 μm or more. When an LED is fabricated using the substrate for a vertical LED according to an embodiment of the invention, a temperature may be raised up to 1000° C. or higher during processing. Such a change in the temperature may cause a problem in that the base substrate warps under stress. In order to prevent such warping, it is preferred that the base substrate be thicker.

The base substrate 100 may be constituted of a single layer made of a conductive and reflective material.

In addition, the base substrate 100 may be embodied as a multilayer structure in which a reflective layer 120 is formed on a conductive layer 110. It is preferred that the reflectance of the reflective layer 120 be 80% or greater with respect to light that has a wavelength of 300 μm or greater. An additional electrode may be formed on a rear surface of the base substrate 100.

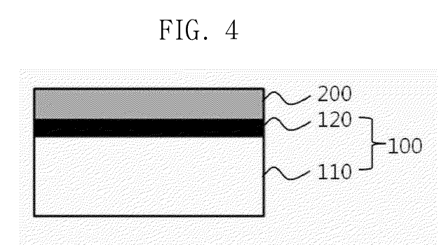

FIG. 4 is a schematic-cross-sectional view depicting a substrate for a vertical LED according to another exemplary embodiment of the invention in which a conductive and reflective base substrate is embodied as a multilayer structure.

Here, the conductive layer 110 may be made of one selected from the group consisting of, but not limited to, Si, GaAs, GaP, AlGaINP, Ge, SiSe, GaN, AlInGaN and InGaN, or made of one selected from the group consisting of, but not limited to, Al, Zn, Ag, W, Ti, Ni, Au, Mo, Pt, Pd, Cu, Cr, Fe and alloys thereof.

The reflective layer 120 is designed to adjust the direction of light that is emitted from an active layer (not shown) of an LED so that the light travels in an intended direction. The reflective layer 120 may be made of a metal having great reflectance, such as Ag, Al, Zn, Au, Pt, Ti, Ge, Cu or Ni. The reflective layer 120 may also be made of an oxide or nitride, such as silicon oxide, silicon nitride, aluminum oxide, magnesium oxide or titanium oxide.

In addition, a bonding layer (not shown) may be interposed between the reflective layer 120 and the conductive layer 110, and an anti-diffusion layer (not shown) may be interposed between the bonding layer and the reflective layer. The bonding layer increases bonding force between the conductive layer 110 and the reflective layer 120, thereby preventing the conductive layer from being detached from the reflective layer. The anti-diffusion layer prevents metal elements from diffusing from the bonding layer or the conductive layer 110 into the reflective layer 120, thereby allowing the reflective layer 120 to maintain the reflectance.

The n-type GaN layer 200 may be formed by bonding an n-type GaN thin film onto the base substrate. Alternatively, the n-type GaN layer may be grown by a variety of methods, such as metal organic chemical vapor deposition (MOCVD), molecular beam epitaxy (MBE) or hydride vapor phase epitaxy (HYPE).

If the GaN thin film is a c-plane single crystal GaN thin film, the GaN thin film has the polarity of a GaN face and the polarity of an N face. Since the surface of the n-type GaN layer facing away from the base substrate must be the Ga face, the use of a freestanding GaN thin film may be preferred. However, a nonpolar or semipolar GaN thin film without a c-plane may not be required to be a freestanding GaN thin film.

Since an LED is fabricated by forming an active layer having a multi quantum well (MQW) structure and a p-type GaN layer on the substrate for a vertical LED according to an embodiment of the invention as described above, it is possible to fabricate a vertical LED without an additional process such as bonding or LLO unlike in the related art. This consequently simplifies the process of fabricating a vertical LED and improves its yield.

The process of fabricating a vertical LED of the related art includes forming a chemical semiconductor layer on a sapphire substrate, bonding the resultant structure including the sapphire substrate and the chemical semiconductor layer onto a conductive substrate, and then removing the sapphire substrate. In contrast, when the substrate for a vertical LED that includes a conductive base substrate according to an embodiment of the invention is used, an active layer and a p-type GaN layer may be directly deposited on the substrate, and neither the bonding process nor the sapphire-removing process of the related art is necessary.

Furthermore, two sheets of substrates (including a sapphire substrate and a conductive substrate) are used when fabricating a vertical LED according to the related art. In contrast, an embodiment of the invention uses only one substrate, thereby reducing fabrication cost.

The foregoing descriptions of specific exemplary embodiments of the present invention have been presented with respect to the certain embodiments and drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. A multi-layer substrate for a vertical light-emitting diode, comprising:
a conductive and reflective base substrate; and
an n-type gallium nitride (GaN) layer formed on the base substrate.

2. The multi-layer substrate of claim 1, wherein the base substrate comprises a single layer.

3. The multi-layer substrate of claim 1, wherein
the base substrate comprises a conductive layer and a reflective layer formed on the conductive layer, and
the n-type gallium nitride (GaN) layer is formed on the reflective layer.

4. The multi-layer substrate of claim 3, further comprising:
a bonding layer interposed between the conductive layer and the reflective layer; and
an anti-diffusion layer interposed between the bonding layer and the reflective layer.

5. The multi-layer substrate of claim 3, wherein the conductive layer comprises one selected from the group consisting of Si, GaAs, GaP, AlGaINP, Ge, SiSe, GaN, AlInGaN and InGaN.

6. The multi-layer substrate of claim 3, wherein the conductive layer comprises one selected from the group consisting of Al, Zn, Ag, W, Ti, Ni, Au, Mo, Pt, Pd, Cu, Cr, Fe and alloys thereof.

7. The multi-layer substrate of claim 3, wherein the reflective layer comprises one selected from the group consisting of Ag, Al, Zn, Au, Pt, Ti, Ge, Cu and Ni.

8. The multi-layer substrate of claim 1, wherein a reflectance of the base substrate is 50% or greater with respect to light that has a wavelength of 300 μm or greater.

9. The multi-layer substrate of claim 1, wherein a coefficient of thermal expansion of the base substrate ranges from 2.5 to 7.5.

10. The multi-layer substrate of claim 1, wherein a thickness of the base substrate is 700 μm or greater.

11. A method of manufacturing a multi-layer substrate for a vertical light-emitting diode, comprising:
preparing a conductive and reflective base substrate; and
forming an n-type gallium nitride (GaN) layer on the base substrate.

12. The method of claim 11, wherein the base substrate comprises a single layer.

13. The method of claim 11, wherein
preparing the base substrate comprises preparing a conductive layer and forming a reflective layer on the conductive layer,
forming the n-type gallium nitride (GaN) layer comprises forming the n-type gallium nitride (GaN) layer on the reflective layer.

14. The method of claim 11, wherein a reflectance of the base substrate is 50% or greater with respect to light that has a wavelength of 300 μm or greater.
